(19) United States
(12) Patent Application Publication
(10) Pub. No.: US 2026/0118307 A1
(43) Pub. Date: Apr. 30, 2026

(54) ELEMENTARY ELECTRODE, ELECTRODE AND ELECTROCHEMICAL DETECTION DEVICE COMPRISING SUCH AN ELECTRODE

(71) Applicant: DIAMSENS, MEYLAN (FR)

(72) Inventors: Yves BIGAY, SAINT-ISMIER (FR); Farhad ABEDINI, CROLLES (FR)

(21) Appl. No.: 19/143,227

(22) PCT Filed: Dec. 27, 2023
(86) PCT No.: PCT/EP2023/087856

§ 371 Date: Jun. 25, 2025

(30) Foreign Application Priority Data
Dec. 27, 2022 (FR) FR2214558

(51) Int. Cl. G01N 27/30; C23C 14/06; C23C 14/16; C23C 14/58; C23C 16/27; C23C 16/56; G01N 27/416; G03F 7/20

(52) U.S. Cl. CPC G01N 27/308; C23C 14/0605; C23C 14/16; C23C 14/5873; C23C 16/278; C23C 16/56; G01N 27/416; G03F 7/20

(57) ABSTRACT

Elementary electrodes with at least two characteristic dimensions smaller than 1 μm or 2.5 μm, including a reactive surface, with characteristic dimensions smaller than 1 μm or 2.5 μm, a thin film of catalyst, part of the surface of which is comprised in the reactive surface, a thin film of carbon, in an allotropic form of carbon chosen from boron-doped diamond and nitrogen-doped amorphous non-hydrogenated carbon, in contact with the said thin film of catalyst and part of the surface of which is included in the reactive surface, a support, in contact with at least one of the thin films, enabling electrical measurements.

The current environmental considerations lead to an increasing concern of the population on the integrity and perennity of the media in contact with which it is located. Under such circumstances, the population has obvious security and quality control needs of those media.

The water constitutes an essential life medium, however the increase in industrial, agricultural, domestic and urban activities and more generally economic results in a degradation of the supply sources which is not without consequence on the uses (e.g. food, recreational, industrial.) which are made of this liquid. In order to ensure suitability between water quality and its use, it is essential to have in situ analysis tools and methods capable of continuously and in real time tracking the evolution of the composition of the aqueous media.

The analysis tools and methods used today are generally based on chemical, optical, electrochemical or biological measurement principles. Sensors generally feature a sensitive surface enabling recognition of the species with which it interacts, and a transducer system transforming the interaction into an electrical signal. Sensors are generally coupled to an electronic system for acquiring, processing and transmitting the electrical signal. This electronic system is generally referred to as the “reading system”.

The electrochemical sensors enable the detection of ionic species in liquid solution. The qualified electroactive species generally correspond to species that dissociate in ionic form in a liquid medium and particularly in an aqueous medium. In this family of compounds, in particular inorganic salts, such as heavy metal salts, acids and bases, dissolved gases are found.

The main expectations around the sensors relate in particular to their sensitivity and their detection limit, which must be consistent with the desired level of concentration of the species of interest, as well as their precision. It is also possible to mention in their desired characteristics a small footprint, a low energy consumption, the least resource consumption related to their production and a relatively short response time for the relevant application. When such specifications are fulfilled, the sensor is an instrument actually useful for performing in-situ measurements or controlling online methods.

When the sensor is permanently immersed in an aqueous medium, it will be subjected to both strong mechanical and chemical stress, as well as gradual fouling of mineral or biological origin. These operating constraints will have an impact on measurement accuracy and sensor life.

Electrochemical sensors are classified into different categories according to the detection mode on which they are based: in particular, potentiometric, amperometric and conductivity sensors.

Potentiometric and amperometric sensors generally use a plurality of electrodes in contact with the solution of interest:
A so-called “working” electrode:
   It serves to qualify the presence of at least one electro-active species;
   Historically, working electrodes have often been made from a plate in solid “noble” (i.e. oxidation-resistant) metal, such as gold or platinum;
   The invention mainly concerns the structure and manufacture of this type of electrode;
A so-called«reference«electrode:
   It must have an invariable electrical potential, whatever the composition of the medium in which it is immersed. By convention, in water, the scale of potentials takes as its origin the potential of the “normal hydrogen electrode”, an electrode generally using a platinum electrode;
   For simpler (less expensive) and more compact designs, a silver-silver chloride electrode is generally used. However, the stability and lifetime of a silver-silver chloride electrode are not optimal when the electrode is immersed in a medium with a variable chloride content;
A possible “auxiliary” electrode:
   It is also referred to as “counter electrode”;
   It is used in amperometric sensors to collect the signal generated at the surface of the working electrode in the form of an electric current;
   It is typically made of metal, particularly noble metals.

Conductivity sensors use combinations of two or four electrodes.

It has been shown that the electrochemical sensors using a working electrode made of a single material are generally sensitive to many chemical species. Although readout techniques can sometimes be used to detect certain chemical species preferentially, for example with voltage scanning techniques where current peaks appear at voltage values associated with certain compounds, species with similar responses and present in the same solution to be analyzed disrupt the measurement.

The addition of catalysts, particularly in the form of nanoparticles, on the surface of a working electrode has been shown to improve a sensor's analytical performance in terms of specificity, selectivity and sensitivity. For example, the publication “Nanoparticles in electrochemical sensors for environmental monitoring” (Trends in Analytical Chemistry, Volume 30, Issue 11, 2011, Pages 1704-1715, https://doi.org/10.1016/j.trac.2011.05.009) provides a partial review of the effectiveness of catalysts, particularly for the use of metal-type nanoparticles or their oxides.

Nanoparticles can be deposited on the surface of the working electrode using electroplating methods. However, nanoparticle adhesion is generally insufficient to achieve a sufficiently long electrode lifetime, especially for environmental monitoring applications. What's more fine-tuning the deposition conditions as a function of the catalyst may prove difficult.

In particular, the invention aims to solve problems encountered in the field of electrochemical devices and associated methods for analyzing solutions and media, by proposing an electrode structure using catalysts. Such a structure is easily adapted to the nature of each catalyst. The nature of the materials and the structure are defined to extend the life of immersed sensors and maintain measurement accuracy at all times in a wide variety of aqueous media.

To this end, the invention has as its object an elementary electrode having at least two characteristic dimensions which are less than 1 μm or 2.5 μm, comprising:
A reactive surface, the characteristic dimensions of which being less than 1 μm or 2.5 μm,
A thin film of catalyst, part of the surface of which is comprised in the reactive surface,
A thin film of carbon in an allotropic form of carbon selected from boron-doped diamond and nitrogen-doped amorphous non-hydrogenated carbon, in contact with said thin film of catalyst and having part of its surface comprised in the reactive surface,
A support, in contact with at least one of the thin films, enabling electrical contact to be made.

Advantageously, an intermediate thin film is arranged between the support and a thin film of carbon or catalyst.

Advantageously, the reactive surface consists solely of part of the surface of the thin film of carbon and part of the surface of the thin film of catalyst.

Advantageously, the surface of the thin film of catalyst comprised in the reactive surface represents 20 to 50% of the reactive surface.

Advantageously, the reactive surface has a non-statistical morphology.

Advantageously, each point on the surface of the thin film of catalyst comprised in the reactive surface is at a distance of less than 250 nm or 400 nm or 1000 nm from at least one point of the surface of the thin film of carbon comprised in the reactive surface.

Advantageously, the thin film of carbon is in the form of boron-doped diamond with a boron concentration of between 10¹⁸ and 3·10²¹ atoms·cm⁻³.

Advantageously, the thin film of carbon is in the form of non-hydrogenated amorphous nitrogen-doped carbon of the ta-C: N type.

The invention also relates to an electrode, comprising a plurality of elementary electrodes according to the invention.

Advantageously, elementary electrodes are present on 60 to 100% of the reactive surface of the working electrode.

A particular embodiment relates to an electrode comprising a plurality of elementary electrodes each having at least two characteristic dimensions smaller than 1 μm or 2.5 μm, said elementary electrodes each having:
A reactive surface, the characteristic dimensions of which being less than 1 μm or 2.5 μm,
A thin film of catalyst, part of the surface of which is comprised in the reactive surface,
A thin film of carbon, in an allotropic form of carbon selected from boron-doped diamond and nitrogen-doped amorphous non-hydrogenated carbon, in contact with said thin film of catalyst and having part of its surface comprised in the reactive surface,
A support, in contact with at least one of the thin films, enabling electrical contact to be made,
   the reactive surface having a non-statistical morphology, the support being common to the elementary electrodes and the reactive surface of the electrode consisting of the reactive surfaces of the elementary electrodes.

Advantageously, each point on the surface of the thin film of catalyst comprised in the reactive surface is at a distance less than or equal to 400 nm or 1000 nm from at least one point of the surface of the thin film of carbon comprised in the electrode reactive surface.

Advantageously, the reactive surface has a three-dimensional structuring obtained by a specific abrasion step of an upper layer to allow a lower layer to be in contact with the medium of interest.

Advantageously, the thin film of catalyst and the thin film of carbon are superimposed.

Advantageously, the surface area of the thin film of catalyst comprised in the reactive surface accounts for 10 to 65% of the reactive surface or 20 to 50% of the reactive surface.

Advantageously, the thin film of catalyst is above the thin film of carbon, the reactive surface comprising central pillars, connected to their nearest neighbors by walls, of round, polygonal or square shape, and of characteristic dimension comprised between 50 and 1600 nm, for example between 50 nm and 100 nm, obtained by etching the thin film of catalyst.

Advantageously, the electrode comprises an electrically insulating layer, for example of oxide or nitride, delimiting a closed frame surrounding and delimiting the reactive surface of the electrode.

Advantageously, the insulating layer is deposited on a layer selected from the thin film of carbon and the thin film of catalyst and an intermediate thin film and on the support so as to be in direct physical contact with the layer and the support.

The invention also relates to a printed circuit assembly comprising a printed circuit board comprising at least one electrode according to any of the preceding claims and a protective layer of polymer, the electrode being fixed to one face of the printed circuit, the insulating layer separating the protective layer from the reactive surface.

The invention also relates to a device for electrochemical detection of at least one electro-active species in a liquid medium comprising:
At least one working electrode is an electrode according to the invention,
At least one reference electrode,
An electrochemical measuring system intended to be connected to the working electrode and the reference electrode.

Advantageously, the electrochemical detection device comprises:
A first printed circuit board comprising or on which are fixed:
   (a) the working electrode,
   (b) the reference electrode,
A second printed circuit board comprising an electrochemical measurement system intended to be connected to said electrodes.

Advantageously, the first and second printed circuit boards form a single printed circuit board on a first side of which the various electrodes are grouped together, and on the second side of which the electrochemical measurement system and, where appropriate, the reading and control system of non-electrochemical sensor is arranged.

The invention also relates to a network of devices for detection according to the invention in which the electrochemical electrochemical measurement system of each of the devices is able to communicate with a central measurement system.

The invention also relates to a method for preparing an electrode according to the invention, on a support, comprising:
a step of depositing a thin film of catalyst,
a step of depositing a thin film of carbon (5) in an allotropic form of carbon chosen from boron-doped diamond and nitrogen-doped amorphous non-hydrogenated carbon,
at least one step of depositing a photoresist,
at least one step of selectively exposing the photoresist,
at least one step of partially removing the photoresist,
at least one step of etching the upper thin film not protected by the residual photoresist,
at least one step if removing residual photoresist.

Advantageously, the method is a method of collectively preparing a plurality of electrodes, in which the support is common to the electrodes.

Further features and advantages of the invention will become apparent from the following detailed description, with reference to the attached figures, which illustrate:

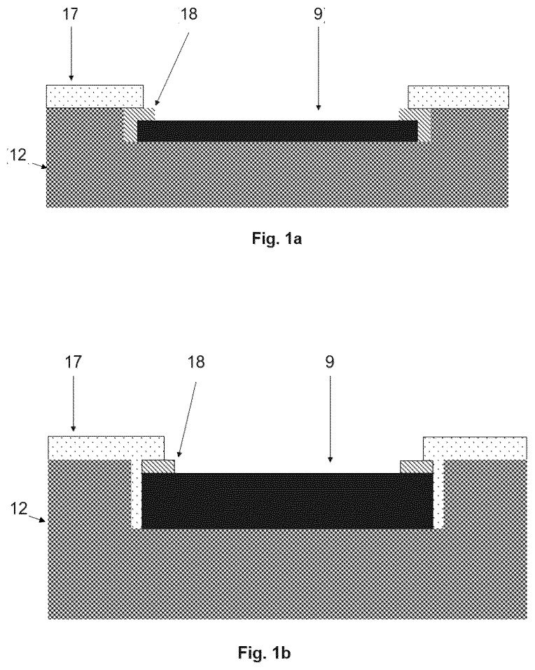

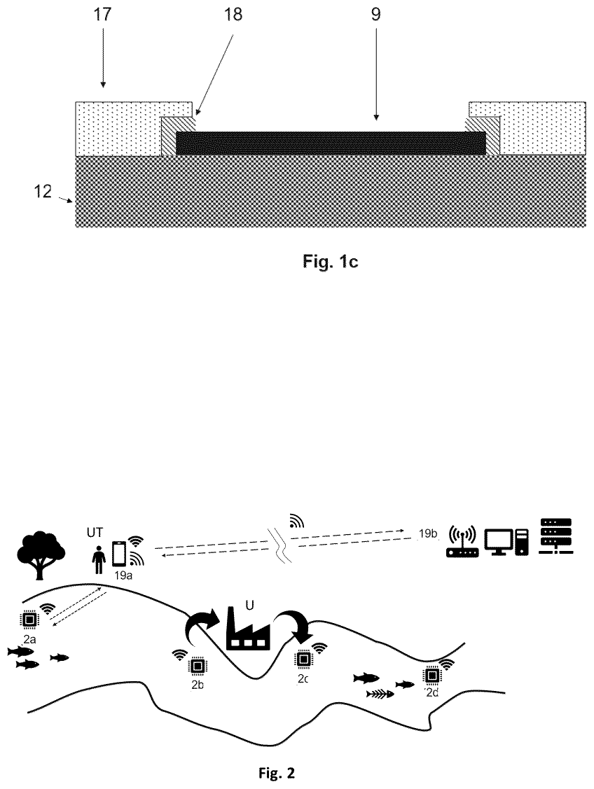

FIG. 1a: Schematic illustration of a printed circuit board comprising or on which are fixed a working electrode, according to the invention, a protective layer and an intermediate layer, in which the circumference of the working electrode is physically insulated from the printed circuit board by an intermediate layer,

FIG. 1b: Schematic illustration of a printed circuit board comprising or on which are fixed a working electrode, according to the invention, a protective layer and an intermediate layer, in which the periphery of the working electrode is physically insulated from the printed circuit board by a protective layer,

FIG. 1c: Schematic illustration of a printed circuit board comprising or on which are fixed a working electrode, according to the invention, a protective layer and an intermediate layer, in which the periphery of the working electrode is physically insulated from the printed circuit board by an intermediate layer,

FIG. 2: Schematic illustration of the use of a network of devices for continuous analysis of the quality of river water used by an industrial plant,

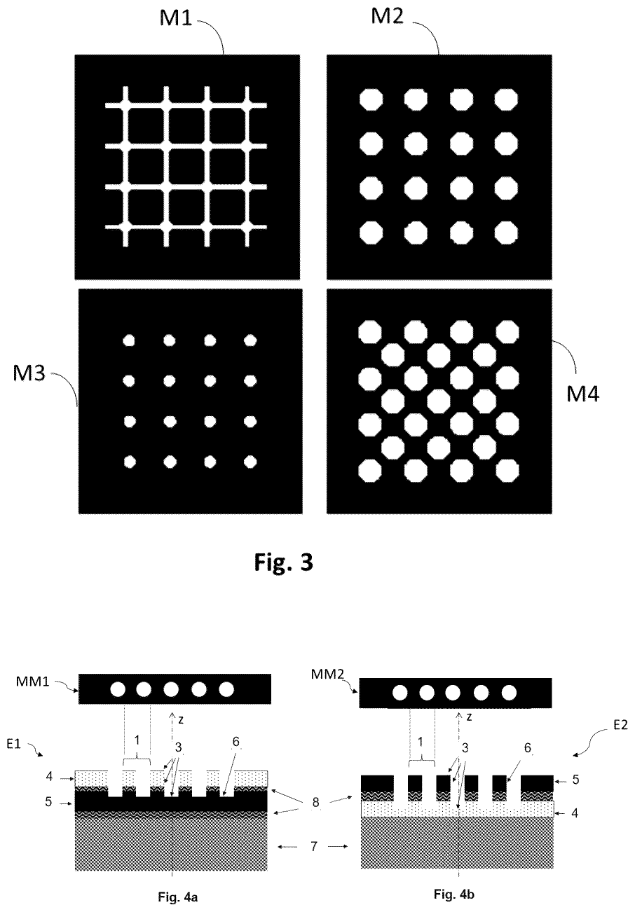

FIG. 3: Schematic illustration of mask configurations used to produce electrodes,

FIG. 4a: Schematic illustration of a mask facing an electrode in which the thin film of carbon is beneath the thin film of catalyst,

FIG. 4b: Schematic illustration of a mask facing an electrode in which the thin film of catalyst is beneath the thin film of carbon,

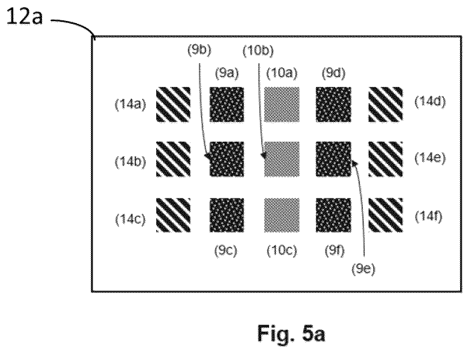

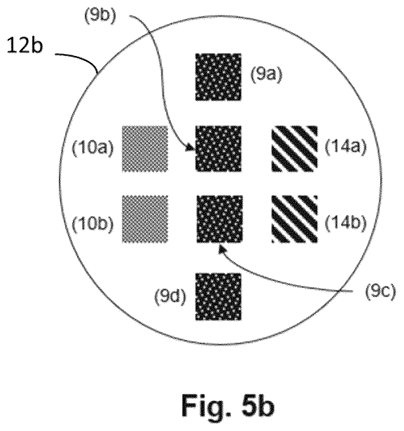

FIG. 5a: Schematic illustration of electrode organization on a rectangular printed circuit board,

FIG. 5b: Schematic illustration of electrode organization on a circular printed circuit board,

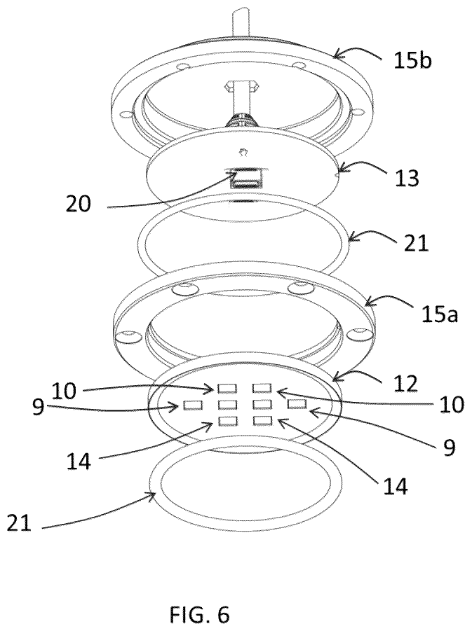

FIG. 6: Schematic illustration of an exploded view of an electrochemical detection device,

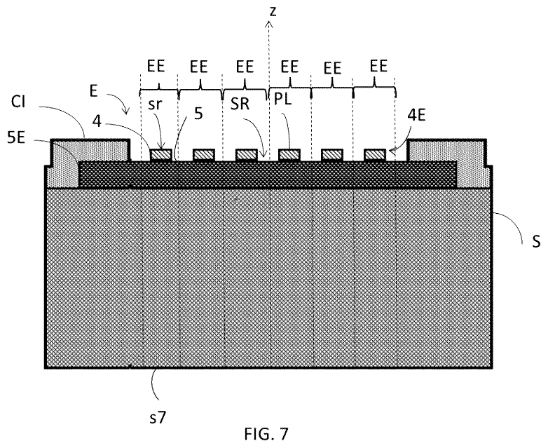

FIG. 7: a schematic representation of a cross-sectional view of an example of an electrode according to the invention,

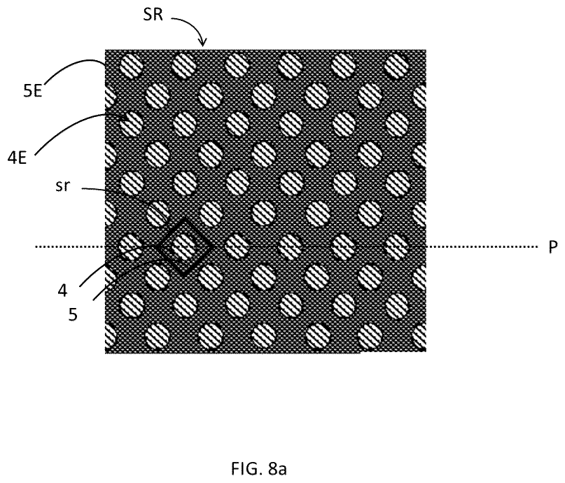

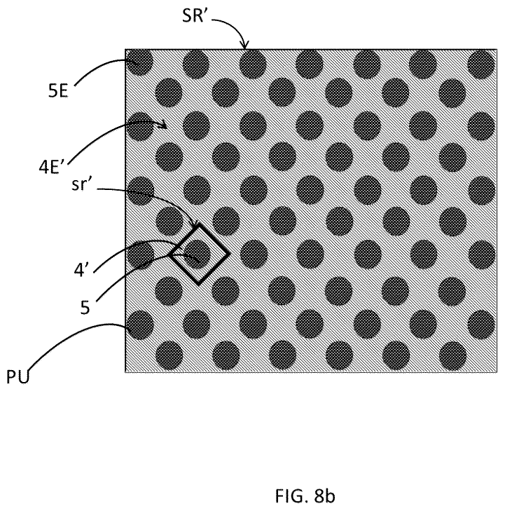

FIG. 8a: a schematic representation of a top view of the active surface of the electrode in FIG. 7 and the plane P in which the cross-section of FIG. 7 is made,

FIG. 8b: a schematic representation of a top view of an active surface of another example of an electrode according to the invention,

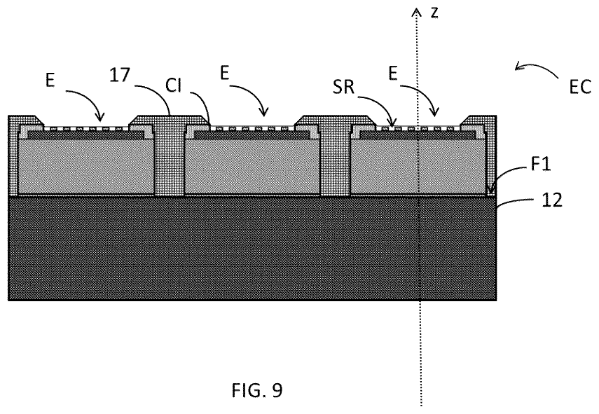

FIG. 9: a schematic cross-sectional view of an assembly comprising a printed circuit on which the electrodes of FIG. 7 are arranged.

### ELEMENTARY ELECTRODE

The invention relates in particular to an elementary electrode 1, two examples of which are shown in FIGS. 4a and 4b.

More precisely, the invention relates to an elementary electrode 1, at least two characteristic dimensions of which are less than 1 μm or 2.5 μm, characterized in that it comprises:
A reactive surface 3, the characteristic dimensions of which being less than 1 μm or 2.5 μm,
A thin film of catalyst 4, part of the surface of which is comprised in the reactive surface 3,
A thin film of carbon 5, in an allotropic form of carbon selected from boron-doped diamond and nitrogen-doped amorphous non-hydrogenated carbon, in contact with said thin film of catalyst 4 and part of the surface of which being comprised in the reactive surface 3,
A support, in contact with at least one of the thin films, enabling electrical contact to be made.

This support is advantageously a part of the support referenced 7 on FIGS. 4a and 4b common to a plurality of elementary electrodes in the non-limiting example shown on these figures.

In other words, the elementary electrode 1 comprises a stack of a plurality of layers along a stacking axis z.

The stacking axis z is therefore defined as the axis along which the layers are stacked.

The stacking axis z is shown as a dotted line in FIGS. 4a and 4b.

The plurality of layers comprises a support on which the thin film of catalyst 4 and the thin film of carbon 5 are stacked or deposited so that:
the characteristic dimensions of the reactive surface 3 are less than 1 μm or 2.5 μm,
part of the surface of the thin film of catalyst 4 is comprised in the reactive surface 3,
part of the thin film of carbon 5 is comprised in the reactive surface 3.

Advantageously, as in the non-limiting examples of FIGS. 4a to 4c, the thin film of catalyst 4 and the thin film of carbon 5 are stacked one on top of the other.

In other words, the thin film of catalyst 4 and the thin film of carbon 5 are advantageously superimposed.

In other words, a single one of the thin film of catalyst 4 and of the thin film of carbon 5 is bonded to the support 7 or to an intermediate layer 8 separating the thin film of carbon 5 and the thin film of catalyst 4 from the support 7.

This single layer is interposed between the support 7 or the intermediate layer 8, separating the single layer from the support 7, and the other layer taken from the thin film of catalyst 4 and the thin film of carbon 5.

By characteristic dimensions of an elementary electrode, we advantageously mean the dimensions of the elementary electrode. Optionally:
The contact between the thin film of carbon 5 and the thin film of catalyst 4 is made by an intermediate thin film 8, and/or.
At least one intermediate thin film 8 is present between the support 7 and a thin film of carbon 5 or catalyst 3.

In other words, the elementary electrode 1 comprises a first intermediate thin film 8 interposed between the thin film of carbon 5 and the thin film of catalyst 4 along the z-axis and in direct physical contact with the thin film of carbon 5 and the thin film of catalyst 4 and/or a second intermediate thin film 8 interposed, along the z-axis, between the thin film of carbon 5 and the support 7 and in direct physical contact with the thin film of carbon 5 and the support 7 and/or a third intermediate thin film 8 interposed, along the z-axis, between the thin film of catalyst 4 and the support 7 and in direct physical contact with the thin film of catalyst 4 and the support 7.

Two layers in direct physical contact with each other means two contiguous layers.

Advantageously, the elementary electrode 1 has a non-statistical morphology, i.e. it is not possible to obtain such an elementary electrode 1 in series using a statistical manufacturing process.

In particular, this is a morphology specific to top-down manufacturing processes, and in particular a morphology that is regular and reproducible by manufacturing processes including a photolithographic etching step.

In other words, the elementary electrode 1 is advantageously obtained by a manufacturing process comprising a photolithographic etching step.

The manufacturing process comprising the photolithographic etching step is advantageously top-down.

Advantageously, the reactive surface of the elementary electrode has a non-statistical morphology.

Advantageously, the reactive surface of the elementary electrode is obtained by a manufacturing process comprising a photolithographic etching step.

Advantageously, the photolithographic etching step makes it possible to form a three-dimensional pattern on the reactive surface.

Advantageously, the elementary electrode is an elementary working electrode.

### Reactive Surface

The reactive surface 3 of an electrode, in particular of an elementary electrode 1, corresponds to the surface of the electrode intended to be in contact with the solution or medium of interest, and on all or part of which at least one electrochemical reaction is likely to occur.

According to a specific embodiment, the reactive surface consists solely of part of the surface of the thin film of carbon and part of the surface of the thin film of catalyst.

Alternatively, part of at least one intermediate layer 8 is comprised in the reactive surface 3, as in the examples shown in FIGS. 4a and 4b.

Preferably, the surface area of the thin film of catalyst 4 within the reactive surface 3 is between 10% and 65%, preferably 20 to 50%. This ensures good measurement performance and efficient, low-energy cleaning of the entire reactive surface of the electrode.

Advantageously, the reactive surface of the elementary electrode is inscribed within the perimeter of a square whose sides have a length of less than 2.5 μm or 1 μm.

According to a specific embodiment, the reactive surface of the elementary electrode lies within the perimeter of a square whose sides measure from 10 to 1000 nm, preferably from 50 to 200 nm.

This square is advantageously taken in a plane perpendicular to the z-axis.

The characteristic dimensions of the reactive surface 3 of electrode 1 are advantageously taken to mean the dimensions of a rectangular parallelepiped in which the reactive surface is inscribed. This rectangular parallelepiped is for example square-based.

In a specific embodiment, the length of each of the sides is between 10 nm and a length of less than 2500 nm or 1000 nm, preferably between 50 and 200 nm.

Advantageously, the reactive surface of the elementary electrode has a three-dimensional structure, i.e. it is not uniformly flat.

According to this specific embodiment, the thin films of catalyst and carbon are superimposed and the three-dimensional structuring is then typically obtained by specific abrasion, for example using a photolithographic etching process, of the upper layer to enable the lower layer to be in contact with the medium of interest.

The lower layer and the upper layer are advantageously selected from the thin film of catalyst and the thin film of carbon.

The upper layer is the layer that is etched to release the bottom layer so that it can be in direct physical contact with the outside environment.

As a result, the surface of the upper layer is partly free for specific abrasion and the bottom layer is covered by the upper layer.

The upper layer is advantageously separated from the substrate 7 by the lower layer.

The morphology of the hollowed structure can be a groove or a pillar with a substantially round, square or hexagonal cross-section.

In other words, the recess is shaped like a groove or well with a round, square or hexagonal cross-section.

As the recess is created by specific abrasion, it opens onto the surface of the upper layer opposite the substrate.

The width of a groove or the diameter of a pillar is of the order of 10 nm to 1200 nm or 500 nm, preferably 50 nm to 200 nm, advantageously between 70 nm and 100 nm.

The height of the groove or well for clearing a pillar is substantially greater than the height of the thin film.

This last thin film is advantageously the top etched thin film.

Advantageously, the reactive surface 3 comprises at least one three-dimensional structure, preferably a pillar or well. Advantageously, the reactive surface 3 also comprises a substantially flat surface adjoining the three-dimensional structure.

For example, the reactive surface 3 comprises a pillar or well with an adjoining peripheral surface.

This peripheral surface is advantageously a surface from which the recess is hollowed out or from which the pillar protrudes.

Advantageously, the peripheral surface is a surface of the lower layer when contiguous to a pillar.

Advantageously, the peripheral surface is a surface of the top layer when contiguous to a recess.

Advantageously, the peripheral surface is substantially flat.

Advantageously, the peripheral surface is substantially perpendicular to the z-axis.

Advantageously, the height of the recess is less than the dimensions of the recess in the plane perpendicular to the z-axis. The height is taken along the z-axis.

### Support

In the sense of the invention, the support for making electrical contact is composed of at least one layer of conductive or semiconductive material.

The use of such a material enables either polarization of the reactive surface, or detection of the electrical signal generated by redox reactions at the reactive surface.

According to a specific embodiment, the support comprises a single layer of material, preferably of conductive or semiconducting material.

The thickness of the support is generally chosen so that it is easy to handle, particularly during the manufacture of electrodes or a device as defined, and does not break due to mechanical stresses associated with mass production. According to a specific embodiment, the support has a thickness of between 200 and 3,000 μm, preferably between 250 μm and 2,000 μm, more preferably between 500 μm and 800 μm or 1,000 μm.

Alternatively, the support comprises a plurality of layers of material.

### Thin Film

Advantageously, by thin film we mean a layer with a thickness of between 0.01 μm and 2 μm.

### Thin Film of Carbon

According to a particular embodiment, the allotropic form of the carbon in the thin film is non-hydrogenated amorphous diamond-like carbon or “DLC”, and the thickness of the layer is between 0.01 μm and 1 μm or 2 μm.

Advantageously, the thickness of the thin film of non-hydrogenated amorphous diamond-like carbon or “DLC” is less than 1 μm, typically between 30 and 100 nm, preferably between 50 and 70 nm.

According to another particular embodiment, the allotropic form of the thin film of carbon is boron-doped diamond or “BDD”, and the layer thickness here is between 0.01 μm and 2 μm, preferably between 0.1 μm and 2 μm, more preferably between 0.5 and 1.5 μm.

### Thin Film of Catalyst

Typically, the thin film of catalyst 4 has a thickness of between 10 nm and 1000 nm, preferably between 20 nm and 500 nm, advantageously between 50 nm and 200 nm.

According to a particular structuring mode, each point on the surface of the thin film of catalyst comprised in the reactive surface is at a distance of less than or equal to 1000 nm from at least one point on the surface of the thin film of carbon comprised in the reactive surface, preferably less than or equal to 500 nm, advantageously less than 250, preferably less than 200 nm, most preferably between 50 and 100 nm.

This feature has the surprising advantage of enabling effective self-cleaning of the entire reactive surface by excitation, i.e. polarization of the elementary electrode by an electrical signal when the reactive surface is in contact with an aqueous solution.

### Intermediate Thin Film

Typically, each intermediate thin film 8 has a thickness of 200 nm or less.

Advantageously, each intermediate thin film 8 has a thickness of between 5 nm and 50 nm, preferably between 5 nm and 20 nm.

The intermediate thin film that may be present between the support and a thin film (of carbon or catalyst), or between each thin film, i.e. separating thin films stacked one on top of the other, is sometimes referred to as a bonding thin film, since its composition is chosen in such a way as to promote adhesion between the various elements.

Its thickness is usually around a hundred or ten nanometers. When it is made of the same materials as the layers it separates, it is typically less than 20 nm.

### Electrode

The invention also relates to an electrode characterized in that it comprises:
A reactive surface with a three-dimensional structure having at least two characteristic dimensions smaller than 1 μm or 2.5 μm,
A thin film of catalyst, a part of the surface of which is comprised in the reactive surface,
A thin film of carbon, in an allotropic form of carbon selected from boron-doped diamond and nitrogen-doped amorphous non-hydrogenated carbon, in contact with said thin film of catalyst and having a part of its surface comprised in the reactive surface,
A support, in contact with at least one of the thin films, for electrical measurements.

The invention also relates to an electrode characterized in that it comprises a plurality of elementary EE electrodes as previously described.

An example of such an electrode is shown in FIGS. 7 and 8a.

In FIG. 7, dotted lines delimit the elementary electrodes EE comprised in the electrode E comprising a plurality of elementary electrodes EE sharing the same support S.

Each elementary electrode EE is advantageously an elementary electrode as defined above comprising:
reactive surface sr, whose characteristic dimensions, as defined above, are less than 1 μm or 2.5 μm,
A thin film of catalyst 4, a part of which surface is comprised in the reactive surface sr,
A thin film of carbon 5, in an allotropic form of carbon selected from boron-doped diamond and nitrogen-doped amorphous non-hydrogenated carbon, in contact with said catalyst thin film and having a part of its surface comprised in the reactive surface,
A support s7, in contact with at least one of the thin films, enabling an electrical contact to be made.

In the example shown in FIG. 7, the thin films of carbon and of catalyst are contiguous, as are the thin film of carbon and the support. Alternatively, as previously mentioned, the elementary electrode comprises at least one intermediate thin film separating two of these layers.

Advantageously, the reactive surface has a non-statistical morphology.

The elementary electrodes of an electrode may be identical. Alternatively, the electrode may comprise at least two distinct elementary electrodes.

The E electrode advantageously comprises a stack of layers along a stacking z-axis.

In the non-limiting example shown in FIG. 7, the thin film of carbon 5 and the thin film of catalyst 4 are stacked on the support s7 along the z-axis.

Preferably, the elementary electrodes EE share the same support S and/or the same composition and/or the same organization or morphology.

In the example shown in FIGS. 7 and 8a, the elementary electrodes EE of the electrode E share the same support S.

Since the substrate is electrically conductive, the elementary surfaces of the electrodes are all at the same electrical potential.

In other words, the support s7 of each elementary electrode EE is a portion of the support S, which is continuous. This enables the elementary electrodes to be produced collectively to make the electrode.

Advantageously, the elementary electrodes EE share the same thin film of carbon 5E and/or the same thin film of catalyst 4E.

In the non-limiting example shown in FIGS. 7 and 8a, the thin film of catalyst 4 of each of the elementary electrodes EE is deposited on the thin film of carbon 5, itself deposited on the support s7.

In other words, the thin film of carbon 5 is interposed between the thin film of catalyst 4 and the support s7.

In this example, the elementary electrodes EE of electrode E share the same thin film of carbon 5E. In other words, the thin film of carbon 5 of each of the elementary electrodes EE is part of the continuous thin film of carbon 5E of electrode E.

In one embodiment of the invention, the E electrode is obtained by juxtaposing elementary electrodes of the same composition.

The reactive surface SR of electrode E advantageously consists of the sum of the reactive surfaces sr of the elementary electrodes EE.

In other words, the reactive surface SR of electrode E consists of all the reactive surfaces sr of the elementary electrodes EE.

If required, this reactive surface SR of the electrode can have the same characteristics as these, in particular with regard to: the different three-dimensional structures, and the distance between each point on the surface of the thin film of catalyst comprised in the reactive surface and at least one point of the surface of the thin film of carbon comprised in the reactive surface.

Thus, in the non-limiting example shown in FIGS. 7 and 8a, the elementary electrodes are contiguous.

FIG. 8a shows the reactive surface SR of electrode E in plan view. FIG. 7 shows a cross-section of the electrode E along plane P shown in dotted lines FIG. 8a, which plane is perpendicular to the z-axis.

FIG. 8b is a top view of the reactive surface SR′ of an electrode which is a variant of the electrode shown in FIGS. 7 and 8a. This reactive surface SR′ is composed of the reactive surfaces of elementary electrodes.

The reactive surface sr, sr′ of an elementary electrode is shown in bold line in FIGS. 8a and 8b.

In the non-limiting examples shown in FIGS. 8a and 8b, the surface sr, sr′ is a unitary three-dimensional pattern of the reactive surface SR, SR′ of the electrode. Each of the reactive surfaces SR, SR′ comprises the repetition of the same elementary pattern sr, sr′ so as to form a continuous surface composed of the same reactive surfaces sr, sr′ of the elementary electrodes. This continuous surface forms a central part of the reactive surface SR, SR′, the periphery of the reactive surface being composed of portions of this elementary pattern.

In other words, the peripheral elementary electrodes have a three-dimensional reactive surface which is a portion of the reactive surface sr, sr′.

In the example shown in FIGS. 7 and 8a, the layer of catalyst 4E consists of spaced-apart catalyst pillars PL, each catalyst block PL belonging to only one of the elementary electrodes EE.

As a result, the layer of catalyst 4E is discontinuous.

In this way, the reactive surface SR of the electrode E consists of the free surface of the catalyst pillars PL and the free surface of the thin film of carbon 5E on which the pillars PL are deposited, the latter free surface being in the form of a grid surrounding the pillars.

Thus, the reactive surface sr of each elementary electrode comprises at least a part of a surface of a pillar PL of catalyst and a surface of a portion 5 of the thin film of carbon 5E on which the pillar PL is deposited. This pillar is the layer of catalyst 4 of the elementary electrode.

In the variant shown in FIG. 8b, the electrode differs from that of FIG. 8a in that the thin film of catalyst 4E′ of the electrode is a layer pierced with wells so as to enable the surface of the thin film of carbon 5 to be in direct physical contact with the surrounding medium. This configuration results in a layer of catalyst 4E′ with improved mechanical strength.

Thus, the electrode's reactive surface SR′ differs from that of FIG. 7 in that it is consists of the free surface of the catalyst grid 4E′ and of the free surface of the thin film of carbon 5E′ on which the catalyst grid 4E′ is deposited, the latter free surface being discontinuous and consists of elementary surfaces surrounded and delimited by the catalyst grid 4E′.

Thus, the reactive surface sr′ of each elementary electrode comprises at least a part of a surface of a well drilled in a portion 4′ of the catalyst grid 4E′ and of a surface of a portion 5 of the thin film of carbon 5E onto which the well opens.

Alternatively, the wells or pillars are replaced by grooves.

Advantageously, the three-dimensional structuring of the reactive surface is obtained by specific abrasion.

Advantageously, the catalyst PL pillars or PU wells or grooves are formed by a specific abrasion step of an initial thin film of catalyst deposited on the thin film of carbon 5E so as to free a layer of carbon 5E surface.

As a result, the morphology of the reactive surface sr, sr′ of each elementary electrode is non-statistical.

The specific abrasion step includes, for example, a photolithographic etching process.

The invention also applies to the configurations shown in FIGS. 7, 8a and 8b, in which the thin film of carbon and the layer of catalyst are inverted.

In this variant, the reactive surface comprises surfaces of carbon pillars separated by a surface of the layer of catalyst or wells piercing the thin film of carbon separated by a surface of the thin film of carbon.

In this variant, wells or pillars can also be replaced by grooves.

Advantageously, the three-dimensional structuring of the reactive surface is obtained by specific abrasion.

Advantageously, the carbon pillars or wells or grooves piercing the thin film of carbon are produced by a specific abrasion step of an initial thin film of catalyst deposited on the thin film of carbon so as to free the thin film of catalyst.

As a result, the morphology of the reactive surface of each elementary electrode is non-statistical.

The specific abrasion step includes, for example, a photolithographic etching process.

Of course, the arrangements of elementary electrodes shown in FIGS. 8a and 8b are not limitative, and contiguous elementary electrodes may or may not have identical reactive surfaces.

According to one embodiment of the invention, the elementary electrodes EE are present over 1 to 100%, preferably between 60 and 100%, of the reactive surface of the electrode.

Typically, the electrode has the shape of a multilayer plate.

In general, its length and width are between 1 and 20 mm, in particular or for example 5×5 mm or 7×7 mm; it can be substantially circular with a diameter between 1 and 20 mm, and in particular 3 to 10 mm.

Preferably the electrode is a working electrode.

The thickness of the electrode typically corresponds to that of an elementary electrode.

Advantageously, as in the non-limiting example shown in FIG. 7, the electrode E comprises an electrically insulating layer CI forming a closed frame surrounding and delimiting the reactive surface SR and being deposited on the thin film of carbon 5E, the insulating layer CI also being deposited on the support S so as to form a closed frame surrounding and delimiting the thin film of carbon 5E.

In this way, the thin film of carbon 5E is spaced from the edge of the support in the x,y plane, facilitating a cutting step designed to separate collectively manufactured electrodes.

Advantageously, the electrode manufacturing process comprises a step of depositing the thin film of carbon 5E on the support and a photolithographic etching step designed to remove part of the thin film of carbon 5E so that the insulating layer CI can be deposited on the support to form the closed frame surrounding the thin film of carbon 5E.

Advantageously, the insulating layer CI is in direct physical contact with the thin film of carbon 5 and the support S.

Alternatively, the electrode comprises an intermediate thin film interposed between the insulating layer and the thin film of carbon to facilitate bonding between the insulating layer and the layer of carbon.

In this way, the insulating layer CI is in direct physical contact with the intermediate thin film and the substrate S.

In one variant, particularly applicable to the configuration shown in FIG. 8 or to any configuration in which the thin film of carbon is interposed between the support and the thin film of catalyst, the electrically insulating layer forms a closed frame surrounding and delimiting the reactive surface and is deposited on the thin film of catalyst.

Advantageously, the insulating layer is also deposited on the support so as to form a closed frame surrounding and delimiting the thin film of catalyst.

Advantageously, the insulating layer is in direct physical contact with the thin film of catalyst and the support.

In this way, the CI insulating layer is in direct physical contact with the intermediate thin film and the substrate.

Alternatively, the electrode comprises an intermediate thin film 8 interposed between the insulating layer and the thin film of catalyst to facilitate adhesion between the insulating layer and the thin film of catalyst.

The insulating layer is then in direct physical contact with the thin film of catalyst and the support.

Advantageously, the insulating layer CI is stacked on the support S without surrounding the support S in a plane perpendicular to the z-axis.

This is also the case in FIG. 1b when layer 18 is an electrically insulating layer.

Manufacturing an electrode with such a configuration is easy, as the layer CI is deposited on the substrate.

In the case of a collective electrode manufacturing process, the electrodes can be separated by a simple cutting step.

Alternatively, the insulating layer CI surrounds the substrate S. This is particularly the case in FIG. 1a when the layer 18 is an electrically insulating layer.

Each example of an electrode according to the invention may feature an insulating layer as described above.

The insulating layer CI is, for example, an electrically insulating metal oxide, e.g. SiO, SiO2, or alumina, . . . or an electrically insulating nitride, e.g. a silicon nitride, e.g. Si₍₃₎N₄.

These materials provide excellent grip, waterproofing, electrical insulation and chemical inertness qualities.

In particular, the nitride insulating layers are resistant to hydroxyl ions, thus avoiding or limiting the risk of damage to the electrochemical detection device during electrode self-cleaning.

The invention relates to a printed circuit assembly EC, a non-limiting example of which is shown in FIG. 9, comprising a printed circuit 12 and at least one electrode according to the invention, for example a plurality, as in the example of FIG. 9.

The electrode according to the invention is an electrode according to any of the embodiments described in the present application. The electrode is, for example, an electrode E of FIG. 7 as shown in FIG. 9.

Advantageously, as in the example shown in FIG. 9, the electrode E is fixed to one side F1 of the printed circuit board 12.

The E electrode is, for example, bonded, soldered or welded to the printed circuit board.

Advantageously, the printed circuit assembly EC is configured so that the only electrically conductive surface of the electrode E intended to be in direct physical contact with the aqueous medium is the surface of the reagent SR.

Advantageously, the entire reactive surface SR of electrode E is intended to be in physical contact with water.

Advantageously, the printed circuit assembly comprises a protective layer 17 covering the insulating layer CI of each electrode E and, if a plurality of electrodes are present, separating the electrodes deposited on the printed circuit board 12.

Advantageously, the protective layer 17 completely covers the free parts of the face F1 of the printed circuit board separating the electrodes (in the case of a plurality of electrodes) or surrounding the electrode or each of the electrodes.

Advantageously, the protective layer 17 is in direct physical contact with the printed circuit board 12.

The protective layer 17 is fastened to the printed circuit board 12, for example, by a screw-nut system.

Advantageously, the protective layer 17 is separated from the reactive surface SR of the electrode E by the insulating layer CI.

In other words, the protective layer 17 is at a distance from the reactive surface.

This arrangement is applicable to the attachment of any electrode of the invention to a printed circuit board 12.

The insulating layer thus makes it possible to limit the risk of damage to a protective layer by hydroxyl free radicals that may be generated by the surface of the thin film of carbon 5.

The protective layer may be injected around the electrode(s) after protection reactive surface of each electrode, or it can be injected into a mold beforehand to form a part which is then positioned on the electrodes and the first face F2 of the printed circuit board, for example using a screw-nut system.

When the part is first injected into a mold, it is advantageously elastically deformable, so that it can be elastically deformed to position it on the electrodes and the first face of the printed circuit board.

Electrodes can be manufactured collectively using a common support which will be larger than the support of a single electrode. For example, this could be a disc with a diameter of 100 to 300 mm.

They are then advantageously separated, for example by cutting, and transferred onto a printed circuit board like a conventional electronic component.

The invention is particularly suited to liquid media, especially predominantly aqueous media. A medium of interest may thus correspond in particular to water used in human and animal nutrition, swimming pool water, waste water from pipes, water qualified as natural (e.g. rivers, lakes), water used in crops (e.g. fish farming, agriculture), aqueous solutions for bioreactors. The invention is also suitable for liquid media with a high alcohol composition such as alcoholic beverages or alcoholic media in the food industry.

### Specific Use of Elementary Electrodes and Electrodes

The invention also covers the use of at least one elementary electrode or at least one electrode according to the invention in an electrochemical system as a working electrode, reference electrode or auxiliary electrode.

The invention relates to the production of elementary electrodes and electrodes according to the described structures and compositions and the use of such electrodes in an electrochemical measurement device. The electrode structures and compositions described can be used to make a range of working electrodes, and depending on the nature of the catalyst thin film—and particularly in the case of platinum—such electrode structures may also be used to make reference and/or auxiliary electrodes.

### Electrochemical Detection Device in a Liquid Medium

The invention also relates to a device for the electrochemical detection DD, an example of which is shown in FIG. 6 in exploded view, of at least one electro-active species in a liquid medium, characterized in that it comprises:
At least one working electrode 9 as previously defined,
At least one reference electrode 10,
An electrochemical measuring system connectable to said electrodes 9, 10.

The working electrode is an electrode according to any of the embodiments or variants described in the patent application.

Preferably the electrochemical detection device DD comprises:
A first printed circuit board 12, comprising or to which are fixed:
   At least one working electrode 9 as previously defined,
   At least one reference electrode 10,
A second printed circuit board 13 comprising or to which is attached an electrochemical measurement system connected to the first printed circuit board 12 by an electrical connector 20.

In the non-limiting embodiment shown in FIG. 6, the device comprises a number of working electrodes 9, which are electrodes according to the invention, a plurality of reference electrodes 10 and a plurality of auxiliary electrodes 14 on a first printed circuit board 12 associated with a second printed circuit board 13n, protected by O-rings 20 and arranged in a two-part circular plastic housing 15a, 15b. Advantageously, the electrochemical detection device DD comprises a printed circuit assembly EC as previously defined.

The circuit board 12 of the electrochemical detection device DD is advantageously the first circuit board of the electrochemical detection device.

Advantageously, the printed circuit assembly comprises:
At least one electrode according to the invention which is a working electrode,
At least one reference electrode 10.

The electrochemical detection device DD is advantageously configured so that the only electrically conductive surface of the electrode intended to be in contact with the aqueous medium is the surface of the reagent.

Advantageously, the entire reactive surface of the electrode is intended to be in physical contact with water.

According to a particular embodiment the first printed circuit board further comprises or is further attached to:
At least one auxiliary electrode, and/or,
At least one non-electrochemical sensor, and preferably a plurality of sensors of different kinds, such as a temperature sensor, a turbidity sensor or a pressure sensor. According to another embodiment, the second printed circuit board further comprises or is further fastened to:
At least one potentiometric, amperometric or conductimetric measuring system, and/or,
An electronic system for controlling and reading non-electrochemical sensors, and/or.
At least one means for monitoring and self-controlling device status, and/or

At least one means of activating the self-cleaning properties of the surface of the thin film of carbon, by causing the generation of hydroxyl radicals in an aqueous medium. Optionally, the first and second printed circuit boards form a single printed circuit board on a first face of which the various electrodes are grouped together and on the second face of which the electrochemical measurement system, and where applicable the non-electrochemical sensor reading and control electronics, are arranged.

Preferably the device DD also comprises:
A main body 15a, 15b, within which the above-mentioned elements 12, 13, 9, 10 are arranged,
Power supply means connected to the electrochemical measurement system, such as a power grid or autonomous means, such as a battery or cell.

The main body 15a, 15b is typically chosen to provide all of the elements with mechanical stability including the power supply means.

Printed Circuit Board with Electrodes

According to a particular embodiment, the device comprises a plurality of working electrodes as previously defined, in particular between 2 and 20, preferably between 3 and 8.

It is advantageous for the working electrodes to be of different types, in particular in terms of the type of thin film of catalyst. Alternatively, they are identical.

Preferably, for each working electrode, the device includes a reference electrode and, optionally, an auxiliary electrode, depending on the chosen reading method. Thus, to perform potentiometric measurements, a working electrode and a reference electrode are associated, for an amperometric measurement, an auxiliary electrode is associated in addition.

For sequential analysis, it is possible to use the same reference electrode and, if necessary, the same auxiliary electrode. In addition to species detection, electrodes can thus be used for a plurality of purposes, in particular to measure the conductivity of the medium of interest, for example in a reading system dedicated to 2 or 4 electrodes.

According to various embodiments, the device is:
A pH and conductivity measuring device,
A device for measuring pH and conductivity, as well as nitrate and phosphate,
A device for measuring pH, conductivity and dissolved oxygen,
A device for measuring pH, conductivity and chlorine.

### Protective Layer

According to a particular embodiment, examples of which are shown in FIGS. 1a to 1c and 9, a protective layer 17 is present on at least a part of the surface of the first printed circuit board 12.

Such a protective layer 17 protects the surface of the printed circuit board 12 during prolonged immersion in a medium of interest, and also ensures the reliability of measurements, in particular by preventing short-circuits between the medium to be analyzed and the various layers of the electrodes.

The thickness of the protective layer is typically between 0.1 and 1000 μm.

In a specific embodiment, the protective layer partially covers the reactive surface of the one or more electrodes present on the surface of the printed circuit board.

According to a specific embodiment, an intermediate layer can be inserted between the working electrode, according to the invention, comprised in the first printed circuit, and the protective layer, in particular to reinforce adhesion between the layers.

In particular, this configuration avoids the effects of poor adhesion, which can lead to delamination of the protective layer and consequent loss of waterproofing.

In another embodiment of the device, this intermediate layer between the working electrode and the protective layer can be made of a material which is substantially inert to the electrolytic activity of the electrode, and which provides a seal and electrical insulation between the working electrode and the protective layer.

FIGS. 1a, 1b and 1c schematically illustrate a cross-sectional view of a printed circuit board 12 comprising, or to which are attached, a working electrode 9, according to the invention, a protective layer 17 and an intermediate layer 18 according to different implementations of the invention: the periphery of the working electrode 9 is physically insulated from the printed circuit board 12 by a protective layer 17 and/or an intermediate layer 18, depending on the configuration.

By the electrode periphery being physically insulated from the printed circuit board 12 by a protective layer 17 and/or an intermediate layer 18, it is meant that the protective layer 17 and/or the intermediate layer 18 is interposed between the printed circuit board 12 and the electrode periphery over the entire periphery of the electrode.

### Second Circuit Board

According to a specific embodiment, this second printed circuit board 13 comprises or supports components for:
Receiving and responding to commands from external application software,
Selecting and soliciting the electrodes required to form a defined sensor and read the raw measurement values,
Calculating concentrations of chemical species to be analyzed from the raw values and/or auto-corrections (e.g. temperature variation, presence of multiple species, etc.).
Checking the correction operation of the device, including self-diagnosis.
Preferably, the electrochemical detection device is a multi-parameter measurement system, which may also be an “electronic tongue”.

### Main Body of the Device

The main body 15a, 15b may comprise a plurality of parts, typically a part designed to enable contact between at least one working electrode 9, according to the invention, and the medium or solution of interest, and a complementary part designed to enable electrical connections.

In particular, the main body 15a, 15b can be in the form of a hollow housing, such as a box with a parallelepiped, circular or elliptical cross-section, with an upper part 15b designed to accommodate the measurement system arranged on the second printed circuit board 13, and a lower part 15a designed to accommodate the electrochemical measurement system.

The device generally comprises physical isolation means 21 to prevent contact between the electrochemical measuring system and the medium or liquid solution of interest. This may be, for example, a coating of polymer or suitable insulating material or a seal such as an O-ring or a plurality of O-rings 21, in particular or for example made of elastomer such as rubber, polysiloxane, polyurethane.

### Network of Devices

The invention also relates to a network of electrochemical detection devices according to the invention 2a, 2b, 2c, 2d, characterized in that the measurement system of each of the devices 2a, 2b, 2c, 2d is able to communicate with a central measurement system 19b. Communication with the latter may be done in particular in a wired manner or preferably by telecommunication (e.g. radio, WiFi, Bluetooth). Typically, the central measurement system 19a is a computer, tablet or smartphone. An illustrative diagram, applied to the case of continuous analysis of the quality of river water used by an industrial plant, is shown in FIG. 2: it represents a set of independent devices 2a, 2b, 2c, 2d interacting, by telecommunication, with a central measurement system 19b which enables them to be controlled. A first device 2a is placed upstream of the plant, the second 2b in the water collecting zone, the third 2c in the reject zone of the plant and the fourth 2d further downstream of plant U, in order, in particular, to check dilutions and any changes in pollution. As depicted, the UT user can directly control the devices 2a, 2b, 2c, 2d via his smartphone 19a, and is in particular able to calibrate them, check their operation and the type of measurement to be carried out, which in turn interacts with a remote or central system 19b for data storage and processing. The works are presented in Mohammad Salah Uddin Chowdury et al/Procedia Computer Science 155 (2019) 161-168 with additional illustrations of device networks.

### Materials—Thin Film of Carbon

The properties of natural diamond are particularly interesting for applications requiring a long service life, as this material is not susceptible to alteration and its surface clogs less than that of other materials. Materials containing a high proportion of “diamond” are preferred for elementary electrodes and electrodes according to the invention: boron-doped diamond (BDD) and diamond-like carbon (DLC).

### Boron-Doped Diamond (BDD)

As the use of natural diamond is not an option for making electrodes using fewer resources, various synthesis methods have been developed, in particular CVD (“chemical vapor deposition”), with two variants: MWCVD (microwave CVD) or HFCVD (hot filament CVD).

Depending on the synthesis conditions, diamond can be obtained as a single crystal, or in the form of polycrystals with grain sizes ranging from a few micrometers to a few nanometers. The thickness of the layers obtained depends mainly on the length of the synthesis process. In practice, thicknesses of less than 5 μm are sufficient for use in a sensor.

However, diamond is an insulating material. To make it suitable for use as an electrode (i.e. to lower its resistivity to values approaching those of a metal), this material can be doped during synthesis by introducing atoms with a structure close to that of carbon. Boron doping is the method is the most industrially controlled method. It is generally accepted that above a concentration of 3×10²⁰ atoms/cm³, boron-doped diamond enters the zone where it behaves like a metal.

In the context of the invention, when the allotropic form of the chosen carbon is boron-doped diamond, it is preferable for the boron concentration to be between 10¹⁸ and 3·10²¹ atoms·cm⁻³.

### Example of the Use of Boron-Doped Diamond (BDD)

Examples of the preparation and use of BDD layers for sensors are presented in patent WO2017037094A1, which describes a device for electrochemical amperometric detection of at least one electroactive species in a liquid medium using boron-doped diamond electrodes. This device is presented as an “electronic tongue”. It uses a plurality of working electrodes, which react to different compounds because their surfaces have been coated with different metal catalysts.

Catalyst deposition in the form of islands a few nanometers in diameter is achieved here by depositing a thin film and then dewetting it, leading to random fragmentation. The size and position of the islands are therefore themselves random. However, the manufacturing parameters can be used to modulate the mean size.

Nanostructure production is based on a “bottom-up” approach, taking advantage of the specific properties of certain materials which, once deposited on a substrate, demonstrate a statistical capacity for morphological organization—this is known as a statistical preparation process. This is linked to the existence of interaction dynamics between the substrate and the deposited material, the elasticity of the material and the temperature, which lead to coalescence or de-moulding of the material, resulting in a statistical distribution of the material on the substrate surface. From a practical point of view, in the electronics industry, a thin film formed out of thermodynamic equilibrium is generally heated to a sufficiently high temperature to activate surface diffusion or evaporation: the thin film will return to a state of equilibrium and spontaneously transform into a set of three-dimensional islands with a shape characteristic of the phenomenon, thus undergoing a morphological transition known as de-moistening. Demoulding usually takes place by pulling back the edge of the thin film or by forming holes in it. For reasons of mass conservation, the thin film forms a characteristic bead as it recoils, the height of which varies with the rate of dewetting and therefore the surface diffusion kinetics of the atoms making up the film. In the case of the thinnest layers, fractal or spinodal dewetting processes may also occur. Moreover, the statistical nature of this type of phenomenon leads to nanostructures whose dimensions are far from homogeneous and whose locations are unevenly distributed: the heights and the footprint of the nanostructure on the substrate vary considerably over the same observation zone.

The electronic tongue reading system uses the measurements on the various working electrodes to calculate the concentration of a compound of interest for which there is no satisfactory direct measurement (due to lack of specificity of the catalysts or lack of sensitivity).

### Diamond-Like Carbon (DLC)

There are a large number of allotropic carbon forms and carbon structures, each with its own characteristics and properties, and each with its own specific preparation procedures. In these structures, atoms are qualified by their degree of atomic hybridization:
sp3: configuration in which the four valence electrons of carbon are assigned to identical hybrid orbitals oriented towards the vertices of a tetrahedron, and in which each of the valence electrons establishes a σ bond (strong bond); this is the configuration of diamond itself,
sp2: this configuration corresponds to the assignment of three valence electrons to hydride orbitals oriented towards the vertices of a right-angled triangle to establish a σ bond (strong bond), with the last electron able to form a π bond (weak bond),
sp: this configuration corresponds to the assignment of two valence electrons to diametrically opposed orbitals, forming strong bonds (o bond), and the other two electrons to non-hybridized py and pz orbitals (orthogonal to the hybridized orbitals), which form IT bonds (weak bond).

Hydrocarbon compounds, made up in particular of covalently bonded carbon and hydrogen atoms, present a wide variety of structures: hydrocarbons, graphite, . . . . These include a family of amorphous materials based on carbon and hydrogen, which can be synthesized in thin-film form and are generally referred to as diamond-like carbon (DLC) films. According to the International Union of Pure and Applied Chemistry (IUPAC), diamond-like carbon (DLC) films are hard, amorphous films containing a significant fraction of sp3-hybridized carbon atoms and may contain a significant amount of hydrogen. Depending on the deposition conditions that lead to their formation, these films may be entirely amorphous or contain diamond crystallites, and are not referred to as “diamond” unless a complete three-dimensional diamond crystal lattice is proven (IUPAC. Compendium of Chemical Terminology, 2nd ed. (the “Gold Book”). Compiled by A. D. McNaught and A. Wilkinson. Blackwell Scientific Publications, Oxford (1997). Online version (2019-) created by S J Chalk. ISBN 0-9678550-9-8. https://doi.org/10.1351/goldbook).

Within the DLC family, there are four main subfamilies, determined by the presence or absence of hydrogen and the sp3/sp2 hybridization ratio:
a-C″ DLC: non-hydrogenated amorphous carbon containing mainly sp2-hybridized carbon,
a-C: H″ DLC: hydrogenated amorphous carbon containing mostly sp2-hybridized carbon,
ta-C″ DLC: non-hydrogenated amorphous carbon containing mainly sp3-hybridized carbon,
ta-C: H″ DLC: hydrogenated amorphous carbon containing mainly sp3-hybridized carbon.

Even if the resistivity of DLC is more favorable than that of “pure” diamond, it is advisable—as with BDD—to introduce a dopant to lower it. In practice, nitrogen doping is generally preferred.

In the context of the invention, when the allotropic form of carbon chosen is nitrogen-doped amorphous non-hydrogenated carbon, it is preferable for this to be of the “ta-C: N” type, and the thin film of carbon may in particular have the following characteristics:
It contains at least 30%, preferably 50%, of sp3-hybridized carbon, preferably at least 75% and advantageously at most 90%.
Nitrogen doping is less than 5 atomic %, preferably between 2 and 4 atomic %.

### Example of the Use of Diamond-Like Carbon (DLC)

The use of DLC to produce electrodes has also been explored, with the following references illustrating the preparation and use of DLC layers:
U.S. Pat. No. 6,423,193 describes an electrode featuring nitrogen-doped DLC structures (ta-C: N) for electroanalytical and electrosynthetic applications.
   The ta-C: N layer is obtained at room temperature by vacuum deposition of carbon and nitrogen ions on a substrate, which can be of any type, including a silicon wafer.
   A masking process is used during deposition to create an electrode array.
Zeng et al. “Diamond-like carbon (DLC) films as electrochemical electrodes.” Diamond and Related Materials 43 (2014): 12-22, describes experiments conducted around the use of DLC in electrodes.
Patent application US2011/0308942 describes microelectrode arrays for detecting heavy metals in aqueous solutions. These arrays are designed on silicon substrates by depositing a layer of doped DLC and a patterning layer to form a multitude of electrodes.

### Materials—Thin Film of Catalyst

A catalyst is a material whose presence makes it possible to provoke a reaction (electrochemical oxidation-reduction) of interest for the measurement of an ionic compound in a particular analysis medium.

Under the terms of the invention, the thin film of catalyst can be made of a metal, which can be selected from platinum, tungsten, titanium, copper, nickel, aluminum, gold, silver, rhodium, osmium, palladium and ruthenium, or of a metal alloy comprising at least one metal selected from the list shown.

Advantageously, the metal or metal alloy is chosen from those which are susceptible to natural oxidation when exposed to ambient air or to the analysis site, or under a flow of oxygen plasma. In this case, an oxide layer of typical thickness ranging from a few nanometers to a few tens of nanometers is created. The thin film of catalyst within the reactive surface is then wholly or partly an oxide layer.

### Example of Catalyst Use

The publication “Detection of Nitrate/Nitrite Using BDD Electrodes Coated with Metal Nano-Catalysts” (ZRIBI, B. and SCORSONE, E. Multidisciplinary Digital Publishing Institute Proceedings, 2017, vol. 1, no. 4, p. 452) illustrates the comparative performance of a plurality of catalysts that are likely to be used in the context of the invention.

By way of example, we can also mention some thin films of catalyst depending on the species we wish to detect:
Dissolved oxygen: TiO2, Pt, Au—Pd, Cu—Pd, Au—Cu,
Nitrate: CuO, Au—Pt, Au—Ru,
Phosphate: NiOOH,
pH (H+): TiO2, WO3, IrOx.

Catalyst selection is based on both performance and cost considerations. A same catalyst can be used to target different chemical species.

### Materials—Support

Among the semiconductor materials that can be used for the support, mention may be made in particular of silicon.

Among the conductive materials, mention may be made of conductive metal alloys and metals, it may in particular be niobium, tungsten, titanium, copper, steel, aluminum, gold or silver.

According to a specific embodiment, the support comprises a single layer of material, preferably conductive material.

The use of a support S makes it possible to limit the amount of carbon 5 or catalyst 4 used. As a result, a cheap electrode can be obtained by very greatly limiting the amounts of the most expensive materials.

In the embodiment of FIG. 9, the support S comprises a single layer of material.

Alternatively, the support comprises several layers of conductive materials stacked along the z-axis.

### Materials—Intermediate Thin Film

The intermediate thin film is generally made of a material that does not substantially affect the electrical conductivity between the support S and the thin film with which it is in contact.

It may in particular be a metal such as titanium and its alloys, copper and its alloys, tungsten, iron alloys, niobium, etc.

Mainly for promoting the adhesion between the different thin films, a specific thin film can be interposed between two functional layers (among carbon film, catalyst film and support).

The intermediate thin film may be an independent material or a mixture of the materials that surround the intermediate layer.

By way of example, mention may be made of:
Titanium is often used as a thin film to bond to DLC carbon,
Niobium is the preferred support material for BDD carbon growth.

### Materials—Protective Layer

In particular, the protective layer can be chosen from waterproof materials that are considered unalterable and offer strong adhesion to the electrode surface.

In particular, it can be a polymer resin, such as polyurethane, silicone, epoxy, etc., or an injectable thermoplastic resin.

Such a protective layer protects the printed circuit board from damage by the aqueous solution, and prevents short circuits between the various electrode layers in the event of infiltration.

An intermediate layer may also be present between the protective layer and the working electrode, chosen for its resistance properties to the electrolytic activity of the electrode.

Metal oxides (SiO2, alumina, etc.) or nitride oxides, which can simultaneously provide good adhesion, sealing, electrical insulation and chemical inertness, are advantageously chosen for this protective layer. The protective oxide or nitride layer can be produced by PVD or by a sol-gel process.

### Preparation Process—Working Electrode

The invention also relates to a process for preparing an electrode as previously defined, on a support, characterized in that it comprises:
A step for depositing a thin film of catalyst,
A step for depositing a thin film of carbon in an allotropic form of carbon chosen from boron-doped diamond and nitrogen-doped non-hydrogenated amorphous carbon,
At least one step of depositing a photoresist,
At least one step of selective exposure of the photoresist,
At least one step of partial removal of the photoresist,
At least one step for etching the upper thin film not protected by the residual photoresist,
At least one step for removing residual photoresist.

The sequence of steps from resin deposition to residual resin removal is an example of specific abrasion.

The thin film of carbon and the thin film of catalyst are deposited on the support.

Advantageously, during the process, the thin film of catalyst and the thin film of carbon are stacked one on top of the other.

In other words, the thin film of carbon and the thin film of catalyst are deposited in such a way that the thin film of carbon is interposed between the thin film of catalyst and the support, or vice versa. The thin film separated from the support by the other thin film is the upper layer.

The photoresist is deposited on the upper layer

The resin is then selectively exposed through a mask and partially removed.

The selective exposure step creates reactions within the photoresist by exposure to light radiation, resulting in chemical modifications. The solubility of the irradiated areas changes according to the type of resin-positive or negative. The specific solvents contained in the developer used during the removal stage will enable the exposed or unexposed resin to be removed according to its solubility and thus, while retaining areas of residual resin, expose the top thin film present on the substrate. Exposure is selective, as it involves the use of a mask, made up of opaque and transparent zones to the applied light radiation and generally arranged on the exposure device, which makes it possible to define the pattern to be reproduced during the etching step.

At the end of the partial photoresist removal step, the part of the photoresist remaining, i.e. not removed, is the residual photoresist.

By etching the upper thin film not protected by the residual photoresist, the electrode's reactive surface can be three-dimensionally structured according to the aforementioned dimensional characteristics.

The residual photoresist is then removed.

At the end of this last stage, the entire reactive surface is formed.

Thus, during the etching step, the upper layer taken among these two layers is etched down to the lower of these two layers, so that a surface of the lower layer forms a part of the reactive surface.

In other words, a part of the surface of the lower layer is free. It is therefore intended to be in contact with the medium of interest.

In this way, the etching step forms a three-dimensional pattern of the reactive surface sr of each of the elementary electrodes EE so as to form the three-dimensional pattern of the reactive surface SR of electrode E and to obtain the reactive surface SR after removal of the residual photoresist following the etching step.

In other words, this process produces the final shape of the electrode's thin film of carbon and thin film of catalyst.

Advantageously, the electrode's reactive surface comprises the reactive surfaces of the elementary electrodes or consists of the reactive surfaces of the elementary electrodes.

Therefore, in general, the process includes a specific abrasion step to form the three-dimensional structuring of the electrode's reactive surface.

Once the residual photoresist has been removed, the electrode's reactive surface is free.

Preferably the electrode is a working electrode.

The process preferably includes a step of polishing the substrate to obtain a surface roughness of less than 50 nm, or is carried out with a substrate whose surface roughness is less than 50 nm.

Advantageously, during the process according to the invention, a plurality of electrodes according to the invention are produced collectively.

For this purpose, the support is common to the different electrodes.

Preparation process—Thin Film of Carbon

The thin film of carbon can be deposited using the processes conventionally used in industry, some of which have already been mentioned.

DLC deposition by PVD (physical vapour deposition) has been explored for a plurality of decades, mainly along two axes: control of the sp3/sp2 ratio and inclusion of various dopants to enhance certain properties.

To use DLC as a sensitive layer in an electrochemical sensor, we'll be looking to maximize the sp3/sp2 ratio and include nitrogen doping to reduce the material's resistivity.

High-power pulsed magnetron assisted plasma generation (“HiPIMS”) techniques have emerged to maximize the sp3/sp2 ratio. Numerous publications have presented successive improvements. Examples include:
“Recent progress on high power impulse magnetron sputtering (HiPIMS)”; AIP Advances 9, 035242 (2019); https://doi.org/10.1063/1.5084031;
“High power impulse magnetron sputtering of diamond-like carbon coatings”; J. Vac. Sci. Technol. A 38(4) July/August 2020; doi: https://doi.org/10.1116/6.0000070;
“Optimization of HiPIMS discharges: The selection of pulse power, pulse length, gas pressure, and magnetic field strength”; Journal of Vacuum Science & Technology A 38, 033008 (2020); https://doi.org/10.1116/6.0000079;
“From pulsed-DCMS and HiPIMS to microwave plasma-assisted sputtering: Their influence on the properties of diamond-like carbon films”; Surface and Coatings Technology, Volume 432, 2022, 127928, https://doi.org/10.1016/j.surfcoat.2021.127928.

In the context of the present invention, it is advantageous to optimize the process according to the characteristics sought for a set of sensors, but the invention is not dependent on a particular realization of the process.

The aforementioned patent WO2017037094A1 contains a detailed description of BDD manufacturing methods. Particular embodiments within the meaning of the invention may adopt these conditions.

### Preparation Process—Thin Film of Catalyst

The deposition of the thin film of catalyst, for example of a few tens of nanometres, can also be carried out by the processes conventionally used in industry, some of which have been referred to previously and in particular in patent WO2017037094A1.

### Preparation Process—Etching and Mask

Etching is generally carried out using a photolithographic process, on the outer layer of the electrode being manufactured, as traditionally used in the microelectronics industry.

Typically, the process involves depositing a photoresist, then using a mask to reproduce the desired patterns on the reactive surface of the electrodes, i.e. their three-dimensional structuring as described above. This is followed by exposure to sunlight or light radiation, then removal of the mask. Depending on the type of resin, the exposed part (or the spared part) becomes soluble in a chemical developer. The result is a thin film (of carbon or catalyst) partially covered with resin. The top thin film is then etched, for example using an oxygen ion plasma.

In particular, the mask can be chosen from materials used in new-generation lithography, especially lithography techniques applicable to scales below 2.5 micrometers, e.g. below 1 micrometer, e.g. 800 nm or 500 nm, preferably 200 nm, advantageously below 50 nm. Typically, this is a mask used with microelectronics lithography techniques.

The process can also take advantage of nanoimprinting techniques, e.g. block copolymers in the form of thin films, such as the poly(styrene-b-methylmethacrylate) (PS-b-PMMA) system or polystyrene-block-polydimethylsiloxane (PS-b-PDMS), which can be used with UV radiation. These masks are widely explored in the literature (see in particular: Javier Arias Zapata. Advanced lithography by self-assembly of PS-b-PDMS and associated plasma ething: application to the fabrication of functional graphene nanoribbons arrays. Micro and nanotechnologies/Microelectronics. Université Grenoble Alpes, 2018. English. NNT: 2018GREAT011. Tel-02281286 and Karim Aissou. Pillary of the self-organization of diblock copolymer thin films for microelectronics applications. Matériaux. Université Joseph-Fourier-Grenoble I, 2008. French. Tel-00267271). This type of technique is particularly well suited to high-precision structuring.

### Preparation Process—Printed Circuit Board Electrodes

As with other components, particularly “bare” chips, electrodes of the same composition can be grouped together either in honeycomb boxes or in coils. Pick-and-place robots used in the electronics industry are capable of automatically positioning each electrode on the printed circuit board. The electrodes can be glued or soldered to the PCB contacts provided.

### Preparation Process—Protective Layer

The application of a protective layer, in particular to a printed circuit board, is generally achieved by placing the first printed circuit board, or the device, in a mold and arranging insulating pillars on the electrodes, then coating the surface of the first printed circuit board, on which an intermediate layer may have been previously arranged, with the chosen material using a PVD or sol-gel process. After coating and drying, the circuit is demolded.

### Advantages of the Invention

The manufacturing process used for electrodes and devices according to the invention is extremely simple to implement, thanks in particular to the deposition of solid layers and the use of masks to define the size and distribution of the catalyst surfaces comprised in the reactive surface.

The use of thin interlayers consolidates the adhesion between the elements and enables the combination of thin films of carbon with a wider range of thin films of catalyst. The process is not statistical in nature: specific adjustments and fine-tuning are driven directly by the user through the simple use of a mask, without the need for fine-tuning of deposition and/or dewetting parameters as in statistical deposition processes.

The presence of a thin film of catalyst enhances the specificity of electrochemical measurements carried out with electrodes according to the invention when they are used as working electrodes. In addition, the electrode manufacturing process makes it easy to adjust the proportion of catalyst in the

Thanks to the mechanical strength properties, and in particular the surface hardness, of carbon in the allotropic forms used, the working electrodes have a significantly longer service life than other known electrodes.

What's more, the surface of the thin film of carbon is naturally extremely smooth—its roughness being of the order of a few nanometers—compared with metal electrodes, for example. Surprisingly, this type of surface has been found to be less prone to fouling-particularly of biological origin—than rougher surfaces. When the starting substrate is smooth, as in the case of silicon or a polished metal substrate, this effect is significantly enhanced.

What's more, surprisingly, especially in the distance configurations described and particularly with the structures previously proposed, the self-cleaning properties of the carbon surface in the allotropic forms described, in particular boron-doped diamond, enable sufficient hydroxyl radicals to be generated, by application of an electric current, to decompose organic or inorganic compounds that may have deposited on the reactive surface, including the surface occupied by the thin film of catalyst. This maintains the sensitivity of the sensors and extends their service life. Self-cleaning is also energy-efficient and effective when the aqueous solution is moving at low speed relative to the reactive surface.

The preparation processes also make it possible to design and obtain reference and auxiliary electrodes.

The use of a plurality of working electrodes enables the detection device to benefit from the electrochemical specificity of each of the working electrodes. The networking of electrochemical measurement devices using these electrodes, and in particular within a detection module, makes it easy, in the case of a multiparameter analysis, to obtain a particularly fine response on the quality of the medium or solution of interest thanks to the device. Thus, by combining and processing the signals from each of the working electrodes, a precise signal can be obtained, referred to as a chemical fingerprint. In this configuration, the device has the characteristics of what is commonly referred to as an electronic “tongue” or “nose”.

The proposed devices comprise a modular part, the first printed circuit board or detection module, which:
Can be easily replaced in the device, saving materials in use,
Allows the device to be easily adapted to the type of measurement the user wishes to perform by changing the detection module.

Thanks to its flexibility, the invention makes it possible to design measuring devices and networks of measuring devices to meet the specific requirements of various fields.

### Examples of Realization

The following preparation examples are intended to illustrate the invention, in particular the preparation of elementary electrodes, working electrodes and sensors, in a non-limiting manner.

### Electrode Preparation

To prepare a sensor that meets the expectations of its intended application (see below), it is useful to consider the structuring of the reactive surface of the elementary and working electrodes.

When the thin film of catalyst is beneath the thin film of carbon, reactive base surfaces generally comprising a central well, of round, polygonal or square shape, and with characteristic dimensions between 50 nm and 1600 nm, for example between 800 nm and 1600 nm or between 100 nm and 800 nm or between 50 nm and 100 nm have been produced by etching the thin film of carbon using different masks during their preparation.

These dimensions and shapes are applicable to the elementary electrodes described above.

A thin film of catalyst under or beneath the thin film of carbon means that the thin film of catalyst is interposed between the thin film of carbon and the support.

When the thin film of catalyst is on top of the thin film of carbon, reactive base surfaces with central pillars, possibly connected to their nearest neighbors by walls, of round, polygonal or square shape, and with characteristic dimensions between 50 nm and 1600 nm, for example between 800 nm and 1600 nm or between 100 and 800 nm or between 50 nm and 100 nm were produced by etching the thin film of catalyst using different masks during their preparation. The walls connecting the pillars stiffened the structure. It is worth noting that the presence of the walls increases the relative surface area occupied by the catalyst within the electrode.

The characteristic dimension of a pillar is the side of a square in which the pillar fits.

This dimension is taken in a plane perpendicular to the z-axis.

These dimensions and shapes are applicable to the elementary electrodes described above.

The basic design of the reactive surface of an electrode according to the invention, in particular a working electrode, is obtained by the juxtaposition of catalyst wells or pillars inserted into the carbon surface (or matrix).

For example, a surface can be prepared with wells or pillars (round, square, polygonal in cross-section) of characteristic dimensions between 50 nm and 1600 nm, for example between 800 and 1600 nm, or between 100 and 800 nm, or between 50 and 100 nm, for example of around 100 nanometers in characteristic dimension, spaced at the same distance apart. This results in a well or dot density close to 25% of the total surface area. The density of pillars can easily be modulated by staggering other pillars, to obtain a density close to 45%, or by spacing the pillars two elementary spaces apart (around 200 nm in this case), to obtain a density slightly greater than 10%.

The characteristic dimension of a pillar is the side of a square in which the pillar fits.

This dimension is taken in a plane perpendicular to the z-axis.

These dimensions and shapes are applicable to the elementary electrodes described above.

FIG. 3 schematically illustrates examples of mask configurations M1, M2, M3, M4 used to produce electrodes according to the invention with various three-dimensional structures: the light (white) areas correspond to the open spaces of the masks when the layer of catalyst is below the carbon, the black areas correspond to the open spaces of the masks when the layer of catalyst is above the carbon.

Preparing Working Electrodes with Simple Structures

Working electrodes consisting of a metal support, the surface of which has catalytic properties, and a thin film of carbon have been prepared.

FIGS. 4a and 4b schematically illustrate the correspondence between the type of mask adopted and the cross-sectional structures of electrodes E1, E2 that can be obtained using the mask.

The white zones of masks MM1 and MM2 are zones preventing the passage of radiation used during the exposure step, while the black zones of these masks are zones allowing the passage of radiation used during the exposure step. In other words, the light areas are the clear areas of the MM1 mask.

In the embodiments shown on these figures, each of the electrodes E1, E2 comprises a stack of layers including a support 7, on which a thin film of carbon 5 and the thin film of catalyst 4 are stacked one on top of the other.

FIG. 4a shows the configuration in which the thin film of carbon 5 is beneath the thin film of catalyst 4. In other words, the thin film of carbon 5 is interposed between the support 7 and the thin film of catalyst 4.

In the non-limiting example shown in FIG. 4a, the E1 stack comprises two intermediate layers, one of which is interposed between the thin film of carbon 5 and the thin film of catalyst 4, the other being interposed between the thin film of carbon 5 and the support 7. FIG. 4b shows the preferred configuration in which the thin film of catalyst 4 is beneath the thin film of carbon 5. In other words, the thin film of carbon 5 is interposed between the support 7 and the thin film of catalyst 4.

One advantage of this design is that it limits the risk of separation of the thin film of carbon 5 from the support 7, thus preserving the electrode's self-cleaning properties over time.

In the non-limiting example shown in FIG. 4b, the E2 stack comprises an intermediate layer 8 interposed between the thin film of carbon 5 and the thin film of catalyst 4.

Advantageously, the intermediate layer 8 is contiguous with the thin film of carbon 5 and the thin film of catalyst 4. The advantage of structure 4a is that it is easier to produce etching patterns, since the layer of catalyst is thinner than the diamond layer. The advantage of structure 4b is that the layer of catalyst is mechanically stronger, as it is inserted between the layer of carbon and the support 7.

Electrodes have been made from tungsten, copper and titanium supports. As mentioned above, these catalytically active supports can be advantageously used for the selective detection of pH, nitrate or dissolved oxygen, for example, without prejudging their usefulness for other measurements.

In the case of titanium, the spontaneous formation of a TiC interlayer a few nanometers thick (around 5 nm) was noted when a BDD layer was grown on such a support.

From a practical point of view, the use of such structures, incorporating a solid support with catalytic properties, proves to be resource-saving, as it does not require the additional preparation of a thin film of catalyst.

In other words, in this case, the support is the layer of catalyst.

Preparing Working Electrodes with Complex Structures

The advantage of this structure is that it can be easily adapted to the characteristics of many different catalysts. To reduce the amount of resources required for production, the aim is generally to reduce the number of layers to be deposited. The choice of layer stacking is mainly dictated by the adhesion properties of the individual layers.

During preparation of the thin film of catalyst beneath the thin film of carbon, it was found that:
The bond between a metal catalyst and a metal support is often very good, and if necessary an intermediate thin film between the two metals can be used.
Oxygen plasma etching is easier and faster through a thin film of carbon than through a thin film of catalyst.
The thin film of carbon is naturally harder than the thin film of catalyst, making it more resistant to abrasion, for example when the medium to be analyzed contains suspended particles.

Generally speaking, titanium also provides a good thin intermediate layer with the layer of carbon, whether DLC or BDD. It has also been found that:
The catalytic properties of titanium oxide can be used, for example, to measure dissolved oxygen.
In the case of DLC, good performance was observed for both titanium and chromium.
In the case of BDD, good performances have been observed for titanium, platinum, gold, silver and niobium (it is preferable to add a thin film of catalyst of a different nature for the latter).

In general, too, when two successive layers are deposited by PVD, it was possible to easily deposit a mixture of the two layers a few nanometers thick to form an intermediate thin film, which enhanced the bond between the two layers.

In order to increase surface roughness at the nanometric scale, and facilitate the adhesion of the next layer without the need for an intermediate thin film, plasma treatments have been used (known as surface abrasion or “etching”).

### Preparation Protocols

Deposits were made under conventional conditions for each of the techniques used.

Application with DLC-type carbon:
Use of a 500 μm-thick copper substrate,
PVD deposition of a thin film of tungsten about 50 nm thick,
PVD deposition of a thin film of titanium to a thickness of approx. 50 nm,
PVD deposition of a titanium/DLC interlayer (increasing the amount of DLC and reducing the amount of titanium), at room temperature and up to 300° C., to a thickness of 10 nm,
PVD deposition of a thin film of DLC-type carbon to a thickness of around 100 nm.

Implementation with BDD carbon:
Use of a 500 μm-thick copper substrate,
PVD deposition of a thin film of tungsten about 50 nm thick,
Optional deposition of a thin film of titanium by PVD to a thickness of approx. 50 nm,
Deposition of a thin film of BDD-type carbon by CVD to a thickness of around 500 nm.

In terms of process, it seemed simpler to start with CVD and end with PVD.

In particular, mask installation and etching were carried out with mask configurations as shown in FIG. 3. The unmasked surfaces were used to form pillars with a circular cross-section:
A cross-section of approx. 100 nm, with a closest interwell distance of approx. 100 nm,
A cross-section of approx. 100 nm, with the closest inter-well distance of approx. 20 nm,
A cross-section of around 10 nm, with the closest inter-well distance around 200 nm,
A cross-section of approx. 20 nm, a nearest inter-well distance of approx. 180 nm and a mesh connecting the pillars with a thickness of 10 nm.

These examples are non-limiting. Different dimensions and arrangements can of course be envisaged.

The preparation protocols were implemented using commercially available tools and materials:
Commercial thin film deposition frames, e.g. PVD with characteristics such as: sputtering/vacuum evaporation with particle velocity 4-10 km·s-1/1 km·s-1, working pressure 5·10-3-5·10-2 mbar/5·10-4-5·10-3 mbar, incident particle energy 4-50 eV/0.2 eV;
Commercial thin-film deposition frames, for example in PVD, with features such as: High-power impulse magnetron sputtering (HIPIMS);
Pure or alloyed metal sputtering targets (binary/ternary/quaternary/+), from 99% to 99.999%, or binderless hot-pressed targets (oxides and intermetallics).
Microwave plasma CVD thin-film deposition frames for BDD-type layer of carbons, with power ratings of 6 KW and pressure conditions of 10-200 Torr.

### Device Construction

Various devices have been built and tested, two topologies adopted for the electrodes in these devices are illustrated in FIGS. 5a and 5b: on a rectangular 12a (in FIG. 5a) PCB (approx. 50 mm×80 mm, have a surface area of approx. 5×5 mm) with 15 electrodes and (in FIG. 5b) circular 12b (approx. 50 mm diameter, electrodes have a surface area of approx. 5×5 mm) with 8 electrodes.

After preparation, the working and other electrodes were cut to a surface of approx. 5×5 mm.

These configurations are particularly interesting in terms of the resources required to produce the devices, as they allow optimization of the number of electrodes needed to carry out measurements: for example, using a rectangular printed circuit board, we would typically need to use (6×3)+4 electrodes to provide the device with 6 amperometric sensors and a conductivity measurement capability, but here we can limit the number of electrodes to 15—i.e. 6 working electrodes (9a to 9f), 6 auxiliary electrodes (14a to 14f) and 3 reference electrodes (10a to 10c)—instead of 22, a saving of 7 electrodes.

In order to carry out potentiometric measurements, the devices were tested using at least one reference electrode and one working electrode:
Example of measurement configuration: two pairs of working electrode and reference electrode: (10a)+(9a) or (10a)+(9b) (see table below).
In order to carry out amperometric measurements, the devices were tested using at least three electrodes:
Example of measurement configuration: one working electrode, one reference electrode, one auxiliary electrode (with reference to the table below, which distinguishes between working electrodes: (10)+(9b)+(14), which offers better performance, and (10)+(9a)+(14)).
Configurations in which the total surface area of the auxiliary electrodes is greater (200%) than that of the working electrode offer improved performance, simply by electrically connecting the two available auxiliary electrodes (14a+14b). Simultaneous activation of two reference electrodes (10a+10b) is also possible in the same way.

In order to carry out conductivity measurements, devices were tested using at least two electrodes:
Measurements taken with reference electrodes facing auxiliary electrodes give good results. Measurements taken with a reference electrode opposite a working electrode also give good results.
We have observed that the presence of a metallic catalyst on the working electrode has no effect on the conductivity measurement: this type of measurement exploits only the metallic (conductive) behavior of the electrode.
Measurements carried out with 4 working electrodes aligned give good results, in line with information in the literature on conductivity measurements.

In evaluating the devices, it was found that the use of carbon/platinum electrodes (using the processes of the invention) as reference electrodes was particularly useful:
Solid platinum is traditionally recognized and used as a reference electrode,
Platinum is more resistant/durable than mixed Ag/AgCl structures.

Although alternatives are possible, the choice of a carbon/platinum electrode for the auxiliary electrode is also functional.

Table 1 shows examples of electrode choices (composition for reference and auxiliary electrodes and species detected for working electrodes) for devices.

TABLE 1

| | Reference | | | | | |
|---|---|---|---|---|---|---|
| | electrode | | | | | Number of |
| | material (10) | Measurement | Measurement | Measurement | Measurement | electrodes |
| | and auxiliary | by working | by working | by working | by working | for |
| | electrode | electrode | electrode | electrode | electrode | conductivity |
| Application | material (14) | (9a) | (9b) | (9c) | (9d) | measurement |
| Swimming | Carbon/Pt | | Chlorine | pH | | 2 |
| pool | | | | | | |
| Fertilization | Carbon/Pt | pH | NO₃ | PO₄ | | 2 |
| Fish farm | Carbon/Pt | pH | Oxygen | NO₃ | NO₂ | 2 |
| Drinking | Carbon/Pt | | Chlorine | pH | | 4 |
| water | | | | | | |
| Sanitation | Carbon/Pt | | Oxygen | pH | redox | 4 |
| Rivers | Carbon/Pt | pH | Oxygen | NO₃ | redox | 2 |

The following catalysts were tested for the working electrodes:
pH: tungsten, iridium and ruthenium oxides,
NO3: copper oxides, cobalt oxides or mixtures,
PO4: nickel oxides,
Chlorine: platinum is relevant.
Redox (redox potential) or mixture of any species: gold.

Conductivity could be measured thanks to the presence of a plurality of electrodes, without the need for an additional sensor. The devices could also be equipped with:
A diode temperature sensor (for the medium to be analyzed),
A MEMS pressure sensor,
An optical turbidity sensor.

The electronic components used to build the devices correspond to commercial products.

1. An electrode comprising a plurality of elementary electrodes each having at least two characteristic dimensions which are less than 2.5 μm, said elementary electrodes each having:
a reactive surface the characteristic dimensions of which being less than 2.5 μm,
a thin film of catalyst, part of the surface of which is comprised in the reactive surface,
a thin film of carbon, in an allotropic form of carbon selected from boron-doped diamond and nitrogen-doped amorphous non-hydrogenated carbon, in contact with said thin film of catalyst and having a part of its surface comprised in the reactive surface,
a support, in contact with at least one of the thin films, enabling electrical contact to be made,
the thin films of catalyst and of carbon being superimposed
and the reactive surface having a three-dimensional structuring being obtained by a photolithographic etching of an upper layer to enable a lower layer to be in contact with the medium of interest, the lower layer and the upper layer being taken among the thin film of catalyst and the thin film of carbon, the support being common to the elementary electrodes and the reactive surface of the electrode consisting of the reactive surfaces of the elementary electrodes.

2. The electrode according to claim 1, wherein each point on the surface of the thin film of catalyst comprised in the reactive surface is at a distance less than or equal to 1000 nm from at least one point of the surface of the thin film of carbon comprised in the reactive surface of the electrode.

3. (canceled)

4. (canceled)

5. The electrode according to claim 1, wherein the surface area of the thin film of catalyst comprised in the reactive surface represents 10 to 65% of the reactive surface or 20 to 50% of the reactive surface.

6. The electrode according to claim 1, wherein the thin film of catalyst is above the thin film of carbon, the reactive surface comprising central pillars, connected to their nearest neighbors by walls, having a round, polygonal or square shape, and having a characteristic size between 50 and 1600 nm, for example between 50 nm and 100 nm obtained by etching the thin film of catalyst.

7. An electrode according to claim 1, comprising an electrically insulating layer, for example made of oxide or nitride, delimiting a closed frame surrounding and defining the reactive surface of the electrode.

8. The electrode according to claim 7, wherein the insulating layer is deposited on a layer selected from the thin film of carbon and the thin film of catalyst and an intermediate thin film and on the support so as to be in direct physical contact with the layer and the support.

9. A printed circuit assembly comprising a printed circuit board comprising at least one electrode according to claim 1 and a protective layer of polymer, the electrode being fixed to one face of the printed circuit board, an insulating layer separating the protective layer from the reactive surface.

10. A device for electrochemical detection of at least one electroactive species in a liquid medium comprising:
at least one working electrode being an electrode according to claim 1,
at least one reference electrode,
an electrochemical measuring system intended to be connected to the working electrode and the reference electrode.

11. The device for electrochemical detection of at least one electroactive species in a liquid medium as claimed in claim 10, comprising:
a first printed circuit board comprising:
the working electrode,
the reference electrode,
a second printed circuit board comprising an electrochemical measurement system intended to be connected to said electrodes.

12. The device for electrochemical detection of at least one electroactive species in a liquid medium according to claim 10, in which the first and second printed circuit boards form a single printed circuit board on a first side of which the elementary electrodes are grouped together and on the second side of which the electrochemical measurement system and, where appropriate, the reading and control system of non-electrochemical sensor is arranged.

13. A network of devices for electrochemical detection according to claim 10, characterized in that the electrochemical measurement system of each of the devices is able to communicate with a central measurement system.

14. A method for preparing an electrode according to claim 1, on a support, comprising:
a step of depositing a thin film of catalyst,
a step of depositing a thin film of carbon in an allotropic form of carbon chosen from boron-doped diamond and nitrogen-doped amorphous non-hydrogenated carbon,
at least one step of depositing a photoresist,
at least one step of selectively exposing the photoresist,
at least one step of partially removing the photoresist,
at least one step of etching the upper thin film not protected by the residual photoresist,
at least one step if removing residual photoresist.

15. A method according to claim 14, the method being a method for the collectively preparing a plurality of electrodes in which the support is common to the electrodes.
